(19) United States
(12) Patent Application Publication
(10) Pub. No.: US 2025/0267912 A1
(43) Pub. Date: Aug. 21, 2025

(54) BASE STRUCTURE AND METHOD FOR MANUFACTURING THE SAME, AND SEMICONDUCTOR DEVICE

(71) Applicant: JADE BIRD DISPLAY (SHANGHAI) LIMITED, Shanghai (CN)

(72) Inventor: Wei LV, Shanghai (CN)

(21) Appl. No.: 19/059,285

(22) Filed: Feb. 21, 2025

(30) Foreign Application Priority Data
Feb. 21, 2024 (CN) 202410195604.X

(51) Int. Cl. H10D 62/815; H10D 62/00; H10D 62/824

(52) U.S. Cl. CPC H10D 62/8161; H10D 62/01; H10D 62/824

(57) ABSTRACT

A base structure and a method for manufacturing the base structure, and a semiconductor device are provided. The base structure includes a substrate and a Group III-V superlattice layer. The Group III-V superlattice layer includes a plurality of lattice stack layers stacked on the substrate. A lattice stack layer includes at least two semiconductor layers, and a semiconductor layer includes a first Group III component and a second Group III component. In a same lattice stack layer, a proportion of the first Group III component in a semiconductor layer away from the substrate is less than a proportion of the first Group III component in a semiconductor layer proximate to the substrate. The Group III-V superlattice layer can effectively achieve structural relaxation between the substrate and an epitaxial structure, reduce dislocation density in the epitaxial structure and improve a performance of a device manufactured on the epitaxial structure.

### CROSS-REFERENCE TO RELATED APPLICATIONS

This application claims the priority to Chinese Patent Application No. 202410195604.X, filed on Feb. 21, 2024, and entitled “BASE STRUCTURE AND METHOD FOR MANUFACTURING THE SAME, AND SEMICONDUCTOR DEVICE”, the contents of which are incorporated herein by reference in their entirety.

### FIELD

The present disclosure generally relates to the field of semiconductor manufacturing, and more particularly, to a base structure and a method for manufacturing the base structure, and a semiconductor device.

### BACKGROUND

Group III-V based materials (e.g., GaN-based materials, including GaN, InGaN, AlGaN and AlInGaN, etc.) are widely used in various electronic device fields, such as high-frequency devices, high-temperature devices, high-power devices and optoelectronic devices, etc. Therefore, a heteroepitaxial growth of Group III-V based materials is inevitable.

Group IV based substrates (e.g., Si substrates) have several advantages, such as low price, high quality, high thermal conductivity and good electrical conductivity. In addition, large-size substrates are easy to obtain and compatible with the existing silicon-based integration processes.

However, a growth of a Group III-V based epitaxial structure on a Group IV based substrate is prone to cause mismatch problems.

### SUMMARY

Embodiments of the present disclosure are to reduce mismatch between the Group IV based substrate and the Group III-V based epitaxial structure.

An embodiment of the present disclosure provides a base structure.

The base structure includes a substrate and a Group III-V superlattice layer. The Group III-V superlattice layer includes a plurality of lattice stack layers stacked on the substrate. A lattice stack layer includes at least two semiconductor layers, and a semiconductor layer includes a first Group III component and a second Group III component. In a same lattice stack layer, a proportion of the first Group III component in a semiconductor layer away from the substrate is less than a proportion of the first Group III component in a semiconductor layer proximate to the substrate. One side of the Group III-V superlattice layer away from the substrate is provided with an epitaxial structure, and the epitaxial structure includes the second Group III component.

Accordingly, the present disclosure also provides a semiconductor device. The semiconductor device includes: a base structure according to embodiments of the present disclosure; and an epitaxial structure disposed on one side of the Group III-V superlattice layer away from the substrate.

In addition, the present disclosure also provides a method for manufacturing a base structure.

The method for manufacturing the base structure includes: providing a substrate; forming a Group III-V superlattice layer on the substrate; and configuring an epitaxial structure on one side of the Group III-V superlattice layer away from the substrate. The epitaxial structure includes the second Group III component. A step of forming the Group III-V superlattice layer on the substrate includes forming a lattice stack layer. A step of forming the lattice stack layer includes: sequentially forming at least two semiconductor layers, and a semiconductor layer including a first Group III component and a second Group III component. In the step of forming the Group III-V superlattice layer on the substrate, the step of forming the lattice stack layer is performed multiple times to form a plurality of the lattice stack layers stacked on the substrate. In a same lattice stack layer, a proportion of the first Group III component in a semiconductor layer away from the substrate is less than a proportion of the first Group III component in a semiconductor layer proximate to the substrate.

Compared with conventional technology, embodiments of the present disclosure may have following advantages.

According to embodiments of the present disclosure, the plurality of the lattice stack layers of the Group III-V superlattice layer are stacked on the substrate, a lattice stack layer includes at least two semiconductor layers, and a semiconductor layer includes a first Group III component. In the lattice stack layer, a proportion of the first Group III component in a semiconductor layer away from the substrate is less than a proportion of the first Group III component in a semiconductor layer proximate to the substrate. One side of the Group III-V superlattice layer away from the substrate is provided with an epitaxial structure, and the epitaxial structure includes the second Group III component. The Group III-V superlattice layer disposed on the substrate can effectively achieve structural relaxation between the substrate and the epitaxial structure, reduce a dislocation density in the epitaxial structure and improve a performance of a device manufactured on the epitaxial structure. The Group III-V superlattice layer can also facilitate stress relaxation of the epitaxial structure during a cooling process, reduce cracking in the epitaxial structure and extend a service life of the device.

According to some embodiments of the present disclosure, a high-temperature semiconductor layer is disposed on one side of the Group III-V superlattice layer away from the substrate, and the high-temperature semiconductor layer facilitates the transition between the Group III-V superlattice layer and the epitaxial structure and can thus improve a quality of the epitaxial structure. The high-temperature semiconductor layer can also reduce the mismatch between the Group III-V superlattice layer and the epitaxial structure caused by cooling during a growth of the epitaxial structure, thereby improving a quality of the device.

According to some embodiments of the present disclosure, a quasi-3D semiconductor layer is disposed between the Group III-V superlattice layer and the high-temperature semiconductor layer. The quasi-3D semiconductor layer can effectively reduce the mismatch between the Group III-V superlattice layer and the high-temperature semiconductor layer, reduce a stress to which the high-temperature semiconductor layer is subjected during a growth process, and eliminate elongation dislocations between the quasi-3D semiconductor layer and the substrate, thereby improving a growth quality of the high-temperature semiconductor layer. In one embodiment, the quasi-3D semiconductor layer is matched with the Group III-V superlattice layer in structure, which can reduce a proportion of the first Group III component in the Group III-V superlattice layer, thereby realizing a transition from the transition structure to both a low-temperature semiconductor layer and the high-temperature semiconductor layer with a low proportion of the first Group III component.

### BRIEF DESCRIPTION OF THE DRAWINGS

FIG. 1 schematically illustrates a cross-sectional view of a base structure according to an embodiment of the present disclosure;

FIG. 2 schematically illustrates a cross-sectional view of a base structure according to another embodiment of the present disclosure;

FIG. 3 schematically illustrates a flowchart of a method for manufacturing a base structure according to an embodiment of the present disclosure; and

FIG. 4 schematically illustrates a flowchart showing steps of forming a transition structure on a substrate in the method for manufacturing the base structure according to the embodiment as shown in FIG. 3.

### DETAILED DESCRIPTION

As mentioned in the background, a mismatch problem often occurs when growing a Group III-V based epitaxial structure on a Group IV based substrate in conventional technology. Reasons for the mismatch problem are now analyzed.

The mismatch problems occurred during growing the Group III-V based epitaxial structure on the Group IV based substrate include: a lattice mismatch and a thermal expansion coefficient mismatch.

In terms of the lattice mismatch, the lattice mismatch between a (111) plane of a Group IV (e.g., Si) based substrate used for an epitaxial growth of a Group III-V (e.g., GaN) based epitaxial structure and a (002) plane of the Group III-V (e.g., GaN) based epitaxial structure is as high as −17%, which results in a large number of dislocations in the epitaxial structure, thereby degrading a performance of the device manufactured on the epitaxial structure.

In terms of the thermal expansion coefficient mismatch, the thermal expansion coefficient of a Group III-V (e.g., GaN) based material is much greater than that of a Group IV (e.g., Si) based substrate, with a mismatch degree as high as 115.8%, which results in a huge tensile stress on the epitaxial structure during a cooling process after the growth of the epitaxial structure, reduces a service life of the device, and even causes cracking of the epitaxial structure.

According to some embodiments of the present disclosure, a base structure is provided. The base structure includes a substrate and a Group III-V superlattice layer. The Group III-V superlattice layer includes a plurality of lattice stack layers stacked on the substrate. A lattice stack layer includes at least two semiconductor layers, and a semiconductor layer includes a first Group III component and a second Group III component. In a same lattice stack layer, a proportion of the first Group III component in a semiconductor layer away from the substrate is less than a proportion of the first Group III component in a semiconductor layer proximate to the substrate. One side of the Group III-V superlattice layer away from the substrate is provided with an epitaxial structure, and the epitaxial structure includes the second Group III component.

According to some embodiments of the present disclosure, the Group III-V superlattice layer disposed on the substrate can effectively achieve structural relaxation between the substrate and the epitaxial structure, reduce the dislocation density in the epitaxial structure and improve a performance of a device manufactured on the epitaxial structure. The Group III-V superlattice layer can also facilitate stress relaxation of the epitaxial structure during a cooling process, reduce an occurrence of cracking in the epitaxial structure and extend a service life of the device.

In order to clarify the embodiments of the present disclosure, the embodiments of the present disclosure will be described clearly in detail in conjunction with accompanying figures.

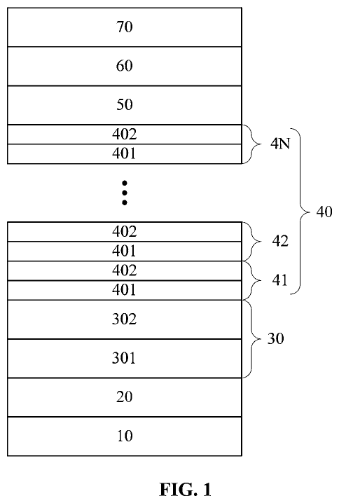

Referring to FIG. 1, a cross-sectional view of a base structure according to an embodiment of the present disclosure is illustrated.

The base structure includes a substrate 10 and a Group III-V superlattice layer 40. The Group III-V superlattice layer 40 includes a plurality of lattice stack layers stacked on the substrate 10. A lattice stack layer includes at least two semiconductor layers, and a semiconductor layer includes a first Group III component. In a same lattice stack layer, a proportion of the first Group III component in a semiconductor layer away from the substrate is less than a proportion of the first Group III component in a semiconductor layer proximate to the substrate. One side of the Group III-V superlattice layer 40 away from the substrate 10 is provided with an epitaxial structure (not shown), and the epitaxial structure includes a second Group III component.

Embodiments of the base structure of the present disclosure are described in detail below in conjunction with the accompanying figures.

The substrate 10 is provided for a mechanical support.

In some embodiments of the present disclosure, the substrate 10 is a Si substrate.

The Group III-V superlattice layer 40 is used to achieve structural relaxation and stress relaxation between the substrate 10 and the epitaxial structure.

The Group III-V superlattice layer 40 can effectively achieve structural relaxation between the substrate 10 and the subsequently formed epitaxial structure, reduce the dislocation density in the epitaxial structure and improve a performance of a device manufactured on the epitaxial structure. The Group III-V superlattice layer 40 can also facilitate stress relaxation of the epitaxial structure during a cooling process, reduce cracking in the epitaxial structure and extend a service life of the device.

The Group III-V superlattice layer 40 is disposed on the substrate 10. The Group III-V superlattice layer 40 includes a plurality of lattice stack layers, and the lattice stack layers are stacked on the substrate 10.

As shown in FIG. 1, the Group III-V superlattice layer 40 includes: a first lattice stack layer 41, a second lattice stack layer 42, . . . , and an Nth lattice stack layer 4N stacked sequentially on the substrate 10 along a direction away from the substrate 10. The first lattice stack layer 41 is disposed on the substrate 10.

In some embodiments of the present disclosure, the Group III-V superlattice layer 40 includes 15 to 60 lattice stack layers, to ensure the effect of structural relaxation and stress relaxation of the Group III-V superlattice layer 40.

The lattice stack layer includes at least two semiconductor layers. The semiconductor layer is a ternary semiconductor layer and includes a first Group III component, a second Group III component and a Group V component, and the first Group III component and the second Group III component are different elemental components.

In some embodiments of the present disclosure, a thickness of the semiconductor layer ranges from 1.7 nm to 16.7 nm. A thickness of any of the semiconductor layers in each lattice stack layer in the Group III-V superlattice layer 40 is appropriate to ensure a quality of the semiconductor layers and the effect of structural relaxation and stress relaxation of the Group III-V superlattice layer 40.

In some embodiments, a thickness of the Group III-V superlattice layer 40 ranges from 0.2 μm to 0.5 μm. The Group III-V superlattice layer 40 has an appropriate thickness to ensure its quality and the effect of structural relaxation and stress relaxation.

In some embodiments of the present disclosure, the base structure is used for a heterogeneous epitaxial growth of a GaN-based material. The Group III-V superlattice layer 40 includes an AlGaN superlattice. The first Group III component is Al, the second Group III component is Ga, and the Group V component is N.

The Group III-V superlattice layer 40 includes at least two semiconductor layers. In some embodiments of the present disclosure, the lattice stack layer includes a first semiconductor layer 401 and a second semiconductor layer 402. The first semiconductor layer 401 is disposed between the second semiconductor layer 402 and the substrate 10, and a proportion of the first Group III element in the second semiconductor layer 402 is less than a proportion of the first Group III element in the first semiconductor layer 401.

The first semiconductor layer 401 and the second semiconductor layer 402 are sequentially stacked on the substrate 10 along a direction away from the substrate 10. A proportion of the first Group III component in one side of the Group III-V superlattice layer 40 proximate to the epitaxial structure is less than a proportion of the first Group III component in one side of the Group III-V superlattice layer 40 proximate to the substrate 10, which can improve the growth quality of the epitaxial structure in the transition of the material of the substrate 10 to the material of the epitaxial structure.

As shown in FIG. 1, the first semiconductor layer 401 of the first lattice stack layer 41 is disposed on the substrate; the first semiconductor layer 401 of the second lattice stack layer 42 is disposed on the second semiconductor layer 402 of the first lattice stack layer 41, . . . , and the first semiconductor layer 401 of the Nth lattice stack layer 4N is disposed on the second semiconductor layer 402 of the (N−1)th lattice stack layer 4(N−1).

In some embodiments, the base structure is used for a heterogeneous epitaxial growth of a GaN-based material. The Group III-V superlattice layer 40 includes an AlGaN superlattice, the first Group III component is Al, and the second Group III component is Ga. The first semiconductor layer 401 is an AlGaN layer, and the second semiconductor layer 402 is an AlGaN layer. In the first semiconductor layer 401, a proportion of an Al component in the Al component and a Ga component ranges from 10% to 30%. In the second semiconductor layer 402, a proportion of an Al component in the Al component and a Ga component ranges from 5% to 15%.

In some embodiments of the present disclosure, the base structure further includes a high-temperature semiconductor layer 70, and the high-temperature semiconductor layer 70 is disposed on one side of the Group III-V superlattice layer 40 away from the substrate 10.

The high-temperature semiconductor layer 70 is a binary semiconductor layer and includes a second Group III component and a Group V component. The high-temperature semiconductor layer 70 can effectively facilitate the transition between the Group III-V superlattice layer 40 and the epitaxial structure. The high-temperature semiconductor layer 70 has a high thermal expansion coefficient, which can reduce the mismatch between the group III-V superlattice layer and the epitaxial structure caused by cooling during a growth of the epitaxial structure, thereby improving a quality of the device.

In some embodiments, a thickness of the high-temperature semiconductor layer 70 ranges from 1.0 μm to 5.0 μm. The high-temperature semiconductor layer 70 has an appropriate thickness to ensure its own quality and the structural transition between the Group III-V superlattice layer 40 and the epitaxial structure, thereby reducing the mismatch between the Group III-V superlattice layer and the epitaxial structure caused by cooling during the growth of the epitaxial structure.

In some embodiments, the base structure is used for a heterogeneous epitaxial growth of a GaN-based material. The Group III-V superlattice layer 40 includes an AlGaN superlattice, the first Group III component is Al, and the second Group III component is Ga. The high-temperature semiconductor layer 70 is a high-temperature GaN layer.

In some embodiments, the base structure further includes a low-temperature semiconductor layer 50, and the low-temperature semiconductor layer 50 is disposed between the high-temperature semiconductor layer 70 and the Group III-V superlattice layer 40.

The low-temperature semiconductor layer 50 is a binary semiconductor layer and includes a second Group III component and a Group V component. The low-temperature semiconductor layer 50 acts as a transition between the Group III-V superlattice layer 40 and the high-temperature semiconductor layer 70, to reduce the lattice mismatch between the Group III-V superlattice layer 40 having a small proportion of the first Group III component and the high-temperature semiconductor layer 70, thereby improving a growth quality of the high-temperature semiconductor layer 70.

In some embodiments, a thickness of the low-temperature semiconductor layer 50 ranges from 5.0 nm to 20 nm. The low-temperature semiconductor layer 50 has an appropriate thickness to ensure its own quality and the structural relaxation between the Group III-V superlattice layer 40 and the high-temperature semiconductor layer 70, thereby improving a growth of the high-temperature semiconductor layer 70.

In some embodiments, the base structure is used for a heterogeneous epitaxial growth of a GaN-based material. The Group III-V superlattice layer 40 includes an AlGaN superlattice, the first Group III component is Al, and the second Group III component is Ga. The high-temperature semiconductor layer 70 is a high-temperature GaN layer, and the low-temperature semiconductor layer 50 is a low-temperature GaN layer.

In some embodiments, the base structure further includes a quasi-3D semiconductor layer 60 disposed between the low-temperature semiconductor layer 50 and the high-temperature semiconductor layer 70.

The quasi-3D semiconductor layer 60 is a binary semiconductor layer and includes a second Group III component and a Group V component. In a plane parallel to a surface of the substrate, the quasi-3D semiconductor layer 60 exhibits an island-like structure. The quasi-3D semiconductor layer 60 can effectively reduce the lattice mismatch between the high-temperature semiconductor layer 70 and the low-temperature semiconductor layer 50, release a stress to which the high-temperature semiconductor layer 70 is subjected during a growth process, and also eliminate elongation dislocations in materials between the high-temperature semiconductor layer 70 and the substrate 10, thereby improving a growth quality of the high-temperature semiconductor layer 70.

In addition, the structural match between the quasi-3D semiconductor layer 60 and the Group III-V superlattice layer 40 can reduce the dependence of the Group III-V superlattice layer 40 on a high proportion of the first Group III component, and realize the transition to the high-temperature semiconductor layer 70 with a low proportion of the first Group III component.

In some embodiments, a thickness of the quasi-3D semiconductor layer 60 ranges from 0.4 μm to 1.0 μm. The quasi-3D semiconductor layer 60 has an appropriate thickness to ensure its quality and island-like structure and achieve structural relaxation, stress relief, and structural matching.

In some embodiments, the base structure is used for a heterogeneous epitaxial growth of a GaN-based material. The Group III-V superlattice layer 40 includes an AlGaN superlattice, the first Group III component is Al, and the second Group III component is Ga. The high-temperature semiconductor layer 70 is a high-temperature GaN layer, the low-temperature semiconductor layer 50 is a low-temperature GaN layer, and the quasi-3D semiconductor layer 60 is a quasi-3D GaN layer.

Referring to FIG. 1, in some embodiments of the present disclosure, the base structure further includes a transition structure 30, and the transition structure 30 is disposed between the Group III-V superlattice layer 40 and the substrate 10.

The transition structure 30 is a binary semiconductor structure and includes a first Group III component and a Group V component. The transition structure 30 can effectively reduce the lattice mismatch between the substrate 10 and the Group III-V superlattice layer 40, and improve a growth quality of the Group III-V superlattice layer 40. In one embodiment, the Group III-V superlattice layer 40 can effectively eliminate elongation dislocations of the transition structure 30, and adjust stresses between the transition structure 30 and the high-temperature semiconductor layer 70.

In some embodiments of the present disclosure, the transition structure 30 includes a roughened semiconductor layer 301 and a smooth semiconductor layer 302, and the smooth semiconductor layer 302 is disposed between the roughened semiconductor layer 301 and the Group III-V superlattice layer 40.

The smooth semiconductor layer 302 is a binary semiconductor layer and includes a first Group III component and a Group V component. The smooth semiconductor layer 302 is disposed between the substrate 10 and the Group III-V superlattice layer 40 and provides a surface for growing the Group III-V superlattice layer 40. The roughened semiconductor layer 301 is a binary semiconductor layer and includes a first Group III component and a Group V component. The roughened semiconductor layer 301 has an island-like structure, which can reduce process requirements during a growth of the smooth semiconductor layer 302 and can thus improve a growth quality of the Group III-V superlattice layer 40.

In some embodiments, at least one of the roughened semiconductor layer 301 and the smooth semiconductor layer 302 has a thickness ranging from 1.0 μm to 3.0 μm. The roughened semiconductor layer 301 and the smooth semiconductor layer 302 have an appropriate thickness to ensure their quality and island-like structure and achieve structural transition.

In some embodiments, the base structure is used for a heterogeneous epitaxial growth of a GaN-based material. The Group III-V superlattice layer 40 includes an AlGaN superlattice, the first Group III component is Al, and the Group V component is N. The substrate 10 is a Si substrate, the roughened semiconductor layer 301 is an AlN roughened layer, and the smooth semiconductor layer 302 is an AlN smooth layer.

In some embodiments of the present disclosure, the base structure further includes an auxiliary growth layer 20 disposed between the roughened semiconductor layer 301 and the substrate 10.

The auxiliary growth layer 20 is used to provide a base for a good growth during the formation of the transition structure 30.

The auxiliary growth layer 20 is a monolithic layer. The auxiliary growth layer 20 includes a first Group III component. In some embodiments, the base structure is used for a heterogeneous epitaxial growth of a GaN-based material. The roughened semiconductor layer is an AlN roughened layer, the smooth semiconductor layer is an AlN smooth layer, the substrate 10 is a Si substrate, and the auxiliary growth layer 20 is an Al layer.

In some embodiments, a thickness of the auxiliary growth layer 20 ranges from 0.3 nm to 1.0 nm. The auxiliary growth layer 20 has an appropriate thickness to ensure its quality and island-like structure and achieve the growth-assisting effect.

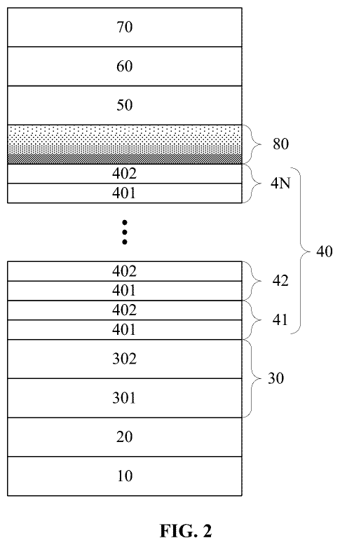

Referring to FIG. 2, a cross-sectional view of a base structure according to an embodiment of the present disclosure is illustrated.

The similarities with the aforementioned embodiments will not be repeated herein. In some embodiments of the present disclosure, the difference from the aforementioned embodiments lies in that the base structure further includes a gradient layer 80 disposed between the Group III-V superlattice layer 40 and the low-temperature semiconductor layer 50, and a proportion of the first Group III component in a portion of the gradient layer 80 away from the substrate 10 is less than a proportion of the first Group III component in a portion of the gradient layer 80 proximate to the substrate 10.

The semiconductor layer of the Group III-V superlattice layer 40 is a ternary semiconductor layer including a first Group III component and a second Group III component, and the low-temperature semiconductor layer 50 is a binary semiconductor layer including a second Group III component.

The gradient layer 80 is disposed on one side of the Group III-V superlattice layer 40 away from the substrate 10, which can reduce the lattice mismatch between the Group III-V superlattice layer 40 and the low-temperature semiconductor layer 50.

In some embodiments of the present disclosure, a proportion of the first Group III component in the gradient layer 80 gradually decreases along a direction away from the substrate 10. The lower the proportion of the first Group III component in the gradient layer 80 is, the closer a lattice constant of the gradient layer 80 is to a lattice constant of the low-temperature semiconductor layer 50 and the better the lattice match is. The higher the proportion of the first Group III component in the gradient layer 80 is, the closer the lattice constant of the gradient layer 80 is to a lattice constant of the Group III-V superlattice layer 40 and the better the lattice match is.

In some embodiments, the gradient layer 80 includes a plurality of gradient semiconductor layers stacked in layers, and a proportion of the first Group III component in the gradient layer 80 decreases layer by layer along a direction away from the substrate 10. In two adjacent gradient semiconductor layers, a proportion of the first Group III component in the gradient semiconductor layer away from the substrate 10 is less than a proportion of the first Group III component in the gradient semiconductor layer proximate to the substrate 10. The first Group III component is uniformly distributed in any one of the gradient semiconductor layers.

In some embodiments of the present disclosure, a proportion of the first Group III component in the gradient layer 80 gradually decreases along a direction away from the substrate 10. In two adjacent gradient semiconductor layers, a proportion of the first Group III component in the gradient semiconductor layer away from the substrate 10 is less than a proportion of the first Group III component in the gradient semiconductor layer proximate to the substrate 10. In addition, the first Group III component is also non-uniform in a same gradient semiconductor layer, and a proportion of the first Group III component in one side away from the substrate is less than a proportion of the first Group III component in one side proximate to the substrate.

The lattice constant of the gradient layer 80 is related to the proportion of the first Group III component in the gradient layer 80. In some embodiments, in order to better match the lattice constant of the Group III-V superlattice layer 40, the lattice stack layer includes a first semiconductor layer 401 and a second semiconductor layer 402, and the first semiconductor layer 401 is disposed between the second semiconductor layer 402 and the substrate 10. A proportion of the first Group III component in the second semiconductor layer 402 is less than a proportion of the first Group III component in the first semiconductor layer 401, and a proportion of the first Group III component in the gradient layer 80 is less than a proportion of the first Group III component in any one of the semiconductor layers of the Group III-V superlattice layer 40.

For example, the Group III-V superlattice layer includes a first semiconductor layer and a second semiconductor layer, and the first semiconductor layer is disposed between the second semiconductor layer and the substrate. The proportion of the first Group III component in the second semiconductor layer is less than the proportion of the first Group III component in the first semiconductor layer, and the proportion of the first Group III component in the gradient layer is less than the proportion of the first Group III component in the second semiconductor layer.

In some embodiments, the number of the semiconductor layers in the gradient layer 80 ranges from 15 to 30. The number of the semiconductor layers in the gradient layer 80 is appropriate, and the quality and the relaxation lattice constant of the gradient layer 80 can be ensured.

In some embodiments, a sum of a thickness of the gradient layer 80 and a thickness of the Group III-V superlattice layer 40 ranges from 0.2 μm to 0.5 μm. The sum of the thickness of the gradient layer 80 and the thickness of the Group III-V superlattice layer 40 are appropriate to achieve a good lattice match between the semiconductor layers with different proportions of the first Group III component, thereby improving a growth quality of the low-temperature semiconductor layer 50, the quasi-3D semiconductor layer 60 and the high-temperature semiconductor layer 70 which are subsequently formed.

It should be noted that in some embodiments, when the base structure includes the gradient layer 80, the number of layers in the Group III-V superlattice layer 40 can be appropriately adjusted to ensure that the sum of the thickness of the gradient layer 80 and the thickness of the Group III-V superlattice layer 40 is within a range.

In some embodiments, the base structure is used for a heterogeneous epitaxial growth of a GaN-based material. The Group III-V superlattice layer 40 includes an AlGaN superlattice, the first Group III component is Al, the second Group III component is Ga, and the Group V component is N. The low-temperature semiconductor layer 50 is a low-temperature GaN layer, and the gradient layer 80 is an AlGaN gradient layer having an Al component decreasing along a direction away from the substrate 10. The lower the proportion of the Al component in the gradient layer 80 is, the closer the lattice constant of the AlGaN gradient layer is to the lattice constant of GaN, and the less the lattice mismatch is.

Accordingly, another embodiment of the present disclosure also provides a semiconductor device.

The semiconductor device includes a base structure according to the embodiments of the present disclosure and an epitaxial structure disposed on one side of the Group III-V superlattice layer away from the substrate.

The embodiments of the base structure can refer to aforementioned embodiments of the base structure and will not be repeated herein.

The epitaxial structure is disposed on one side of the Group III-V superlattice layer away from the substrate. In some embodiments, the epitaxial structure is a Group III-V epitaxial structure. For example, the Group III-V epitaxial structure at least includes the second Group III component.

The Group III-V superlattice layer is disposed between the epitaxial structure and the substrate, and the structure between the substrate and the epitaxial structure can realize good relaxation. The epitaxial structure has a low dislocation density therein and a high quality, thereby achieving a good performance of the semiconductor device.

In one embodiment, the Group III-V superlattice layer is disposed between the epitaxial structure and the substrate, which can relax stresses in the epitaxial structure during a cooling process and reduce cracking of the epitaxial structure. Therefore, the semiconductor device has high stability and reliability.

Accordingly, another embodiment of the present disclosure also provides a method for manufacturing a base structure.

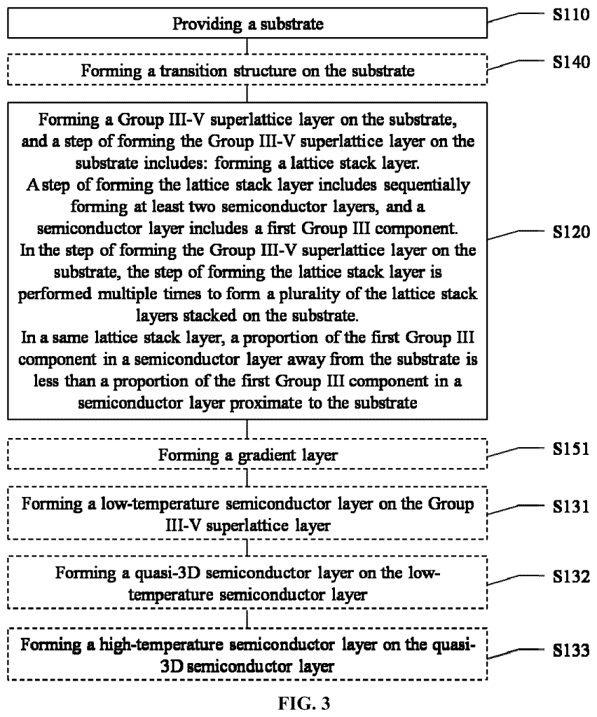

Referring to FIG. 3, a flowchart of a method for manufacturing a base structure according to an embodiment of the present disclosure is illustrated.

With reference to FIG. 1, a cross-sectional view of the base structure manufactured according to some embodiments of the method for manufacturing the base structure as shown in FIG. 3 is illustrated.

The method for manufacturing the base structure includes: step S110, providing a substrate 10; and step S120, forming a Group III-V superlattice layer on the substrate. The step of forming the Group III-V superlattice layer on the substrate includes: forming a lattice stack layer. The step of forming the lattice stack layer includes sequentially forming at least two semiconductor layers, and a semiconductor layer includes a first Group III component. In the step of forming the Group III-V superlattice layer on the substrate, the step of forming the lattice stack layer is performed multiple times to form a plurality of the lattice stack layers stacked on the substrate. In a same lattice stack layer, a proportion of the first Group III component in a semiconductor layer away from the substrate is less than a proportion of the first Group III component in a semiconductor layer proximate to the substrate.

It should be noted that in some embodiments of the present disclosure, the base structure of the present disclosure is manufactured by the method for manufacturing the base structure of the present disclosure. Embodiments of the method may refer to aforementioned embodiments of the base structure.

Firstly, the step S110 is performed to provide the substrate 10.

In some embodiments, in the step S110 of providing the substrate 10, the substrate 10 is a Group IV substrate 10. For example, the substrate 10 is a Si substrate.

In some embodiments of the present disclosure, the method for manufacturing the base structure is performed through an epitaxial growth apparatus. The step S110 of providing the substrate 10 includes placing the substrate in the epitaxial growth apparatus after providing the substrate 10.

After the substrate 10 is provided, the step S120 is performed to form the Group III-V superlattice layer on the substrate 10.

In one embodiment, performing the step S120 of forming the Group III-V superlattice layer on the substrate 10 includes forming a lattice stack layer. The step of forming the lattice stack layer includes sequentially forming at least two semiconductor layers, and the semiconductor layers include a first Group III component. During performing the step S120 of forming the Group III-V superlattice layer on the substrate 10, the step of forming the lattice stack layer is performed multiple times to form a plurality of the lattice stack layers stacked on the substrate. In a same lattice stack layer, a proportion of the first Group III component in a semiconductor layer away from the substrate is less than a proportion of the first Group III component in a semiconductor layer proximate to the substrate.

A growth direction of forming the lattice stack layer is a direction away from the substrate 10. The step of forming the lattice stack layer includes sequentially forming at least two semiconductor layers in a direction away from the substrate 10. In the step S120 of forming the Group III-V superlattice layer on the substrate 10, the step of forming the lattice stack layer is performed multiple times to form the Group III-V superlattice layer 40 of multi-period repetition.

In the same lattice stack layer, the proportion of the first Group III component in a semiconductor layer away from the substrate is less than the proportion of the first Group III component in a semiconductor layer proximate to the substrate. In the same lattice stack layer, the proportion of the first Group III component in a subsequently grown semiconductor layer is less than the proportion of the first Group III component in a formerly grown semiconductor layer.

It should be noted that in some embodiments of the present disclosure, the substrate 10 is a Group IV substrate 10. For example, the substrate 10 is a Si substrate. In the step S120 of forming the Group III-V superlattice layer 40 on the substrate 10, the Group III-V superlattice layer 40 is grown on a (111) crystal plane of the substrate 10.

In some embodiments of the present disclosure, the step of forming the lattice stack layer includes: forming a first semiconductor layer on the substrate, and forming a second semiconductor layer on the first semiconductor layer. Forming the first semiconductor layer includes: providing a first Group III component source. Forming the second semiconductor layer includes: providing a first Group III component source. In the step of forming the lattice stack layer, an amount of the first Group III component source provided to form the second semiconductor layer is less than an amount of the first Group III component source provided to form the first semiconductor layer.

In some embodiments of the present disclosure, the method is provided for manufacturing a base structure used for a heterogeneous epitaxial growth of a GaN-based material. The Group III-V superlattice layer 40 includes an AlGaN superlattice, the first Group III component is Al, the second Group III component is Ga, and the Group V component is N.

For example, during a process of forming the Group III-V superlattice layer 40 on the substrate 10, a temperature of the epitaxial growth apparatus is set to range from 1030° C. to 1100° C., and a pressure is set to range from 50 Torr to 100 Torr.

The method is provided for manufacturing the base structure used for a heterogeneous epitaxial growth of a GaN-based material. In some embodiments, the step of forming the lattice stack layer includes: providing an Al source to form the first semiconductor layer 401, and providing an Al source to form the second semiconductor layer 402 on the first semiconductor layer 401. In the step of forming the lattice stack layer, an amount of the Al source provided to form the second semiconductor layer 402 is less than an amount of the Al source provided to form the first semiconductor layer 401.

In some embodiments, during a process of forming the first semiconductor layer, the amount of the Al source is provided and a proportion of an Al component in the Al component and a Ga component in the first semiconductor layer ranges from 10% to 30%. During a process of forming the second semiconductor layer on the first semiconductor layer, the amount of the Al source is provided and a proportion of an Al component in the Al component and a Ga component in the second semiconductor layer ranges from 5% to 15%.

In some embodiments, the method is provided for manufacturing the base structure used for a heterogeneous epitaxial growth of a GaN-based material. The Group III-V superlattice layer 40 includes an AlGaN superlattice. After setting the temperature of the epitaxial growth apparatus in a range of 1030° C. to 1100° C. and the pressure in a range of 50 Torr to 100 Torr, an Al source (e.g., trimethylaluminum), a Ga source (e.g., trimethylgallium) and an N source (e.g., ammonia gas) are introduced into the epitaxial growth apparatus to grow the first lattice stack layer 41 on the substrate 10.

In the process of growing the first lattice stack layer 41 on the substrate 10, a first AlGaN layer and a second AlGaN layer of the first lattice stack layer 41 are sequentially grown on the substrate 10. The first AlGaN layer is the first semiconductor layer 401 of the first lattice stack layer 41, and the second AlGaN layer is the second semiconductor layer 402 of the first lattice stack layer 41. The amount of the Al source (e.g., trimethylaluminum) provided for growing the first AlGaN layer ensures that the proportion of the Al component in the Al component and the Ga component in the first AlGaN layer ranges from 10% to 30%, and the amount of the Al source (e.g., trimethylaluminum) provided for growing the second AlGaN layer ensures that the proportion of the Al component in the Al component and the Ga component in the second AlGaN layer ranges from 5% to 15%. In one embodiment, during the process of growing the first lattice stack layer 41, the amount of the Al source (e.g., trimethylaluminum) provided for growing the first AlGaN layer is greater than the amount of the Al source (e.g., trimethylaluminum) provided for growing the second AlGaN layer.

After growing the second AlGaN layer on the first AlGaN layer of the first lattice stack layer 41, an Al source (e.g., trimethylaluminum), a Ga source (e.g., trimethylgallium), and an N source (e.g., ammonia gas) are continuously provided to grow the second lattice stack layer 42 on the first lattice stack layer 41.

In the process of growing the second lattice stack layer 42 on the first lattice stack layer 41, a first AlGaN layer and a second AlGaN layer of the second lattice stack layer 42 are sequentially grown on the second AlGaN layer of the first lattice stack layer 41. The first AlGaN layer is a first semiconductor layer 401 of the second lattice stack layer 42, and the second AlGaN layer is a second semiconductor layer 402 of the second lattice stack layer 42. The amount of the Al source (e.g., trimethylaluminum) provided for growing the first AlGaN layer ensures that the proportion of the Al component in the Al component and the Ga component in the first AlGaN layer ranges from 10% to 30%, and the amount of the Al source (e.g., trimethylaluminum) provided for growing the second AlGaN layer ensures that the proportion of the Al component in the Al component and the Ga component in the second AlGaN layer ranges from 5% to 15%. In one embodiment, during the process of growing the second lattice stack layer 42, the amount of the Al source (e.g., trimethylaluminum) provided for growing the first AlGaN layer is greater than the amount of the Al source (e.g., trimethylaluminum) provided for growing the second AlGaN layer, and so forth. After growing a second AlGaN layer on a first AlGaN layer of the (N−1)th lattice stack layer 4(N−1), an Al source (e.g., trimethylaluminum), a Ga source (e.g., trimethylgallium), and an N source (e.g., ammonia gas) are continuously provided for growing the Nth lattice stack layer 4N on the (N−1)th lattice stack layer 4(N−1).

In the process of growing the Nth lattice stack layer 4N on the (N−1)th lattice stack layer 4(N−1), a first AlGaN layer and a second AlGaN layer of the Nth lattice stack layer 4N are sequentially grown on the second AlGaN layer of the (N−1)th lattice stack layer 4(N−1). The first AlGaN layer is a first semiconductor layer 401 of the Nth lattice stack layer 4N, and the second AlGaN layer is a second semiconductor layer 402 of the Nth lattice stack layer 4N. The amount of the Al source (e.g., trimethylaluminum) provided for growing the first AlGaN layer ensures that the proportion of the Al component in the Al component and the Ga component in the first AlGaN layer ranges from 10% to 30%, and the amount of the Al source (e.g., trimethylaluminum) provided for growing the second AlGaN layer ensures that the proportion of the Al component in the Al component and the Ga component in the second AlGaN layer ranges from 5% to 15%. In one embodiment, during the process of growing the Nth lattice stack layer 4N, the amount of the Al source (e.g., trimethylaluminum) provided for growing the first AlGaN layer is greater than the amount of the Al source (e.g., trimethylaluminum) provided for growing the second AlGaN layer.

In some embodiments of the present disclosure, in the process of forming the Group III-V superlattice layer 40 on the substrate 10, the process of forming the lattice stack layer is performed 15 to 60 times and a sum of the thicknesses of the first lattice stack layer 41 to the Nth lattice stack layer 4N in the Group III-V superlattice layer 40 in a range of 0.2 μm to 0.5 μm.

Still referring to FIG. 3, the method further includes: after performing the step S120 of forming the Group III-V superlattice layer 40 on the substrate 10, performing step S131 of forming a low-temperature semiconductor layer 50 on the Group III-V superlattice layer 40, performing step S132 of forming a quasi-3D semiconductor layer 60 on the low-temperature semiconductor layer 50, and performing step S133 of forming a high-temperature semiconductor layer 70 on the quasi-3D semiconductor layer 60.

In some embodiments of the present disclosure, the method is provided for manufacturing the base structure used for a heterogeneous epitaxial growth of a GaN-based material. The Group III-V superlattice layer 40 includes an AlGaN superlattice, the first Group III component is Al, the second Group III component is Ga, and the Group V component is N.

In some embodiments, in the step S131 of forming the low-temperature semiconductor layer 50 on the Group III-V superlattice layer 40, a temperature of the epitaxial growth apparatus is set to range from 950° C. to 1050° C., and a pressure is set to range from 350 Torr to 550 Torr.

In some embodiments, in the process of forming the low-temperature semiconductor layer 50 on the Group III-V superlattice layer 40, a Ga source (e.g., trimethylgallium) and an N source (e.g., ammonia gas) are introduced into the epitaxial growth apparatus, and a low-temperature GaN layer with a thickness ranging from 5 nm to 20 nm is grown on the second AlGaN layer of the Nth lattice stack layer 4N. The low-temperature GaN layer is the low-temperature semiconductor layer 50.

It should be noted that during the process of forming the low-temperature semiconductor layer 50 on the Group III-V superlattice layer 40, the low-temperature semiconductor layer 50 is grown on the Group III-V superlattice layer 40 in an N-rich environment. In some embodiments, in the process of forming the low-temperature semiconductor layer 50 on the Group III-V superlattice layer 40, a ratio of an amount of a provided Ga source to an amount of a provided N source is less than 1 when growing the low-temperature GaN layer on the second AlGaN layer of the Nth lattice stack 4N, and the GaN layer is grown under an environment of high N content.

In some embodiments, in the step S132 of forming the quasi-3D semiconductor layer 60 on the low-temperature semiconductor layer 50, a temperature of the epitaxial growth equipment is set to range from 1000° C. to 1060° C., and a pressure of the epitaxial growth apparatus is set to range from 450 Torr to 600 Torr.

In some embodiments, during the process of forming the quasi-3D semiconductor layer 60 on the low-temperature semiconductor layer 50, a Ga source (e.g., trimethylgallium) and an N source (e.g., ammonia gas) are introduced into the epitaxial growth apparatus, and a quasi-3D GaN layer with a thickness ranging from 0.4 μm to 1.0 m is grown on the low-temperature GaN layer. The quasi-3D GaN layer is the quasi-3D semiconductor layer 60.

In some embodiments, in the step S133 of forming the high-temperature semiconductor layer 70 on the quasi-3D semiconductor layer 60, a temperature of the epitaxial growth apparatus is set to range from 1060° C. to 1100° C., and a pressure of the epitaxial growth apparatus is set to range from 100 Torr to 200 Torr.

In some embodiments, during the process of forming the high-temperature semiconductor layer 70 on the quasi-3D semiconductor layer 60, a Ga source (e.g., trimethylgallium) and an N source (e.g., ammonia gas) are introduced into the epitaxial growth apparatus, and a high-temperature GaN layer with a thickness ranging from 1.0 μm to 5.0 μm is grown on the quasi-3D GaN layer. The high-temperature GaN layer is the high-temperature semiconductor layer 70.

Referring to FIG. 3, the method further includes: after performing the step S110 of providing the substrate and before performing the step S120 of forming the Group III-V superlattice layer on the substrate, performing step S140 to form a transition structure 30 on the substrate 10.

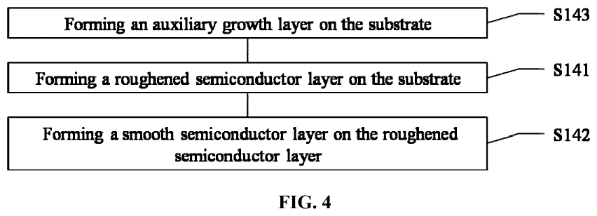

Referring to FIG. 4, in some embodiments, performing step S140 of forming the transition structure 30 on the substrate 10 includes: performing step S141 of forming a roughened semiconductor layer 301 on the substrate 10, and performing step S142 of forming a smooth semiconductor layer 302 on the roughened semiconductor layer 301.

The smooth semiconductor layer 302 is disposed between the roughened semiconductor layer 301 and the Group III-V superlattice layer 40, and the smooth semiconductor layer 302 provides a surface for growing the Group III-V superlattice layer 40. The roughened semiconductor layer 301 is a binary semiconductor layer and includes a first Group III component and a Group V component. The roughened semiconductor layer 301 has an island-like structure, which can reduce process requirements during growing the smooth semiconductor layer 302 and can thus improve a growth quality of the Group III-V superlattice layer 40.

In some embodiments, in the step S141 of forming the roughened semiconductor layer 301 on the substrate 10, a temperature of the epitaxial growth apparatus is set to range from 1030° C. to 1100° C., and a pressure of the epitaxial growth apparatus is set to range from 50 Torr to 150 Torr.

In some embodiments, during the process of forming the roughened semiconductor layer 301 on the substrate 10, an Al source (e.g., trimethylaluminum) and an N source (e.g., ammonia gas) are introduced into the epitaxial growth apparatus to grow an AlN roughened layer with a thickness ranging from 1.0 μm to 3.0 μm on the substrate 10. The AlN roughened layer is the roughened semiconductor layer 301.

In some embodiments, in the step S142 of forming the smooth semiconductor layer 302 on the roughened semiconductor layer 301, a temperature of the epitaxial growth apparatus is set to range from 1030° C. to 1100° C., and a pressure of the epitaxial growth apparatus is set to range from 50 Torr to 150 Torr.

In some embodiments, during the process of forming the smooth semiconductor layer 302 on the roughened semiconductor layer 301, an Al source (e.g., trimethylaluminum) and an N source (e.g., ammonia gas) are introduced into the epitaxial growth apparatus to grow an AlN smooth layer with a thickness ranging from 1.0 μm to 3.0 m on the AlN roughened layer. The AlN smooth layer is the smooth semiconductor layer 302.

In some embodiments, performing the step S140 of forming the transition structure 30 on the substrate 10 further includes: performing step S143 of forming an auxiliary growth layer 20 on the substrate 10 before forming the roughened semiconductor layer 301, and growing the roughened semiconductor layer 301 on the auxiliary growth layer 20 during performing the step S141 of forming the roughened semiconductor layer 301 on the substrate.

In some embodiments, in the step S143 of forming the auxiliary growth layer 20 on the substrate 10, a temperature of the epitaxial growth apparatus is set to range from 1000° C. to 1060° C., and a pressure of the epitaxial growth apparatus is set to range from 50 Torr to 120 Torr.

For example, during the process of forming the auxiliary growth layer 20 on the substrate 10, an Al source (e.g., trimethylaluminum) is introduced into the epitaxial growth apparatus to grow an Al layer with a thickness ranging from 0.3 nm to 1.0 nm on the substrate 10. The Al layer is the auxiliary growth layer 20.

Referring to FIG. 3 in conjunction with FIG. 2, in some embodiments of the present disclosure, the method further includes: after performing step S120 of forming the Group III-V superlattice layer 40 and before performing step S131 of forming the low-temperature semiconductor layer 50, performing step S151 of forming a gradient layer 80.

In some embodiments, the base structure is used for a heterogeneous epitaxial growth of a GaN-based material. The Group III-V superlattice layer 40 includes an AlGaN superlattice, the first Group III component is Al, and the second Group III component is Ga. The low-temperature semiconductor layer 50 is a low-temperature GaN layer, and the gradient layer 80 is an AlGaN gradient layer having a proportion of an Al component decreasing along a direction away from the substrate 10.

In some embodiments, in the step S151 of forming the gradient layer 80, an Al source (e.g., trimethylaluminum), a Ga source (e.g., trimethylgallium) and an N source (e.g., ammonia gas) are introduced into the epitaxial growth apparatus, and the gradient layer 80 is grown on the second semiconductor layer 402 of the Nth lattice stack layer 4N of the Group III-V superlattice layer 40. A sum of a thickness of the gradient layer 80 and a thickness of the Group III-V superlattice layer 40 ranges from 0.2 μm to 0.5 μm.

In some embodiments, in the step S151 of forming the gradient layer 80, an amount of an Al source provided at a first moment is greater than an amount of an Al source provided at a second moment, and the second moment is later than the first moment. During the process of forming the gradient layer 80, the amount of the Al source provided at a relative early moment is greater than the amount of the Al source provided at a relative late moment, which results in a non-uniform distribution of the proportion of the Al component in the gradient layer 80, thereby reducing the lattice mismatch in the transition from the Group III-V superlattice layer 40 to the low-temperature semiconductor layer 50.

In some embodiments, performing the step S151 of forming the gradient layer 80 includes: forming a gradient semiconductor layer. During the process of forming the gradient layer 80, the step of forming the gradient semiconductor layer is performed multiple times to form the gradient layer 80 having a plurality of gradient semiconductor layers stacked in layers. The amount of the Al source gradually decreases each time compared with a previous time during the process of forming the gradient semiconductor layer multiple times.

In some embodiments, during performing the process of forming the gradient semiconductor layer multiple times, in two adjacent steps of forming the gradient semiconductor layer, the amount of the Al source provided in a latter step of forming the gradient semiconductor layer is less than the amount of the Al source provided in a former step of forming the gradient semiconductor layer. However, in each step of forming the gradient semiconductor layer, the amount of the provided Al source remains stable.

In some embodiments, during the process of forming the gradient layer 80, a first gradient semiconductor layer is grown on the second semiconductor layer 402 of the Nth lattice stack layer 4N of the Group III-V superlattice layer 40, and the amount of the Al source provided to grow the first gradient semiconductor layer is less than the amount of the Al source provided to grow the second semiconductor layer 402 of the Nth lattice stack layer 4N.

In some embodiments, during the process of forming the gradient layer 80, a second gradient semiconductor layer is grown on the first gradient semiconductor layer, and the amount of the Al source provided to grow the second gradient semiconductor layer is less than the amount of the Al source provided to grown the first gradient semiconductor layer; . . . ; and an N₁th gradient semiconductor layer is grown on an (N₁−1)th gradient semiconductor layer, and the amount of the Al source provided to grow the N₁th gradient semiconductor layer is less than the amount of the Al source provided to grow the (N₁−1)th gradient semiconductor layer. However, the amount of the Al source provided during the growth of the first gradient semiconductor layer, the amount of the Al source provided during the growth of the second gradient semiconductor layer, . . . , the amount of the Al source provided during the growth of the (N₁−1)th gradient semiconductor layer, and the amount of the Al source provided during the growth of the N₁th gradient semiconductor layer remain stable, respectively.

In some embodiments, in the process of forming the gradient layer 80, the amount of the Al source decreases gradually. In the process of forming the gradient layer, the amount of the Al source decreases successively to form the gradient layer 80 having a gradually decreased Al component.

To sum up, the lattice stack layers of the Group III-V superlattice layer are stacked on the substrate, the lattice stack layer includes at least two semiconductor layers, and the semiconductor layer includes the first Group III component. In the lattice stack layer, the proportion of the first Group III component in a semiconductor layer away from the substrate is less than the proportion of the first Group III component in a semiconductor layer proximate to the substrate. The Group III-V superlattice layer disposed on the substrate can effectively achieve structural relaxation between the substrate and the epitaxial structure, thereby reducing the dislocation density in the epitaxial structure and improving a performance of a device manufactured on the epitaxial structure. The Group III-V superlattice layer can also facilitate stress relaxation of the epitaxial structure during a cooling process, thereby reducing cracking in the epitaxial structure and extending a service life of the device.

Further, the high-temperature semiconductor layer is disposed on one side of the Group III-V superlattice layer away from the substrate, and the high-temperature semiconductor layer can facilitate the transition between the Group III-V superlattice layer and the epitaxial structure and can thus improve the quality of the epitaxial structure. The high-temperature semiconductor layer is can reduce the mismatch between the Group III-V superlattice layer and the epitaxial structure caused by cooling during a growth of the epitaxial structure, thereby improving the quality of the device.

In one embodiment, the quasi-3D semiconductor layer is disposed between the Group III-V superlattice layer and the high-temperature semiconductor layer. The quasi-3D semiconductor layer is can effectively reduce the mismatch between the Group III-V superlattice layer and the high-temperature semiconductor layer, reduce a stress to which the high-temperature semiconductor layer is subjected during a growth process, and eliminate elongation dislocations between the quasi-3D semiconductor layer and the substrate, thereby improving a growth quality of the high-temperature semiconductor layer. In one embodiment, the quasi-3D semiconductor layer can matched with the Group III-V superlattice layer in structure, which can reduce a proportion of the first Group III component in the Group III-V superlattice layer, thereby realizing a transition from the transition structure to both a low-temperature semiconductor layer and the high-temperature semiconductor layer with a low proportion of the first Group III component.

The aforementioned base structure can be applied in a manufacturing process of a micro-display panel.

The micro-display panel described above has a very small volume, with dimensions of length and width ranging from 500 μm to 50,000 μm. An area of a light-emitting region of the micro-display panel is very small, such as 1 mm×1 mm, 2.64 mm×2.02 mm, 3 mm×5 mm, and the like. The light-emitting region of the micro-display panel includes a plurality of micro LED pixels arranged in an array, and a specific pixel arrangement may be one of 320×240, 640×480, 1600×1200, 1920×1080, and 2560×1440. A dimension of a single micro LED pixel ranges from 100 nm to 100 μm. In some embodiments, the dimension of the single micro LED pixel ranges from 150 nm to 15 μm. In some embodiments, the dimension of the single micro LED pixel may also be less than 10 μm.

A driver backplane is configured on a back of the micro LED pixel array and electrically connected with the micro LEDs in the micro LED pixel array. The driver backplane is capable of receiving image data and other signals from external sources and controlling the corresponding micro-LEDs to emit or not emit light. The driver backplane is either a Thin Film Transistor (TFT) board or an Integrated Circuit (IC) board.

In some embodiments, a frame buffer, a column driver circuit, and a row driver circuit are integrated in the driver backplane of the micro-display panel, the frame buffer includes a first pixel storage area, and the micro LED pixel array includes a second pixel storage area. A complete frame of pixel grayscale data from the outside can first enter the first pixel storage area of the frame buffer, the column driver circuit can load the pixel grayscale data from the first pixel storage area of the frame buffer into the second pixel storage area of the micro LED pixel array, and the row driver circuit can scan the pixel grayscale data in the second pixel storage area and generate pulse modulation signals to achieve the display of varying grayscale levels. When driving multiple micro LED pixels in the micro LED pixel array, either a single pixel can be driven independently or a plurality of pixel units can be driven independently, and the specific driving method should not constitute a limitation of the present disclosure.

It should be noted that the above-described application of the base structure in the manufacturing process of micro-display panels should not constitute a limitation on the application of the present disclosure.

Although the present disclosure has been disclosed above, the present disclosure is not limited thereto. Any changes and modifications may be made without departing from the spirit and scope of the present disclosure, and the scope of the present disclosure should be determined by the appended claims.

1. A base structure, comprising: a substrate and a Group III-V superlattice layer;
wherein the Group III-V superlattice layer comprises a plurality of lattice stack layers stacked on the substrate, at least one of the plurality of lattice stack layers comprises at least two semiconductor layers, and at least one semiconductor layer comprises a first Group III component and a second Group III component; and
in a same lattice stack layer, a proportion of the first Group III component in a semiconductor layer away from the substrate is less than a proportion of the first Group III component in a semiconductor layer proximate to the substrate.

2. The base structure according to claim 1, wherein the lattice stack layer comprises a first semiconductor layer and a second semiconductor layer, and the first semiconductor layer is disposed between the second semiconductor layer and the substrate; and
a proportion of the first Group III component in the second semiconductor layer is less than a proportion of the first Group III component in the first semiconductor layer.

3. The base structure according to claim 2, wherein the Group III-V superlattice layer comprises an AlGaN superlattice, and the first Group III component is Al;
a proportion of an Al component in the Al component and a Ga component ranges from 10% to 30% in the first semiconductor layer; and
a proportion of an Al component in the Al component and a Ga component ranges from 5% to 15% in the second semiconductor layer.

4. The base structure according to claim 1, wherein the base structure further comprises:
a high-temperature semiconductor layer, wherein the high-temperature semiconductor layer is disposed on one side of the Group III-V superlattice layer away from the substrate, and a thickness of the high-temperature semiconductor layer ranges from 1.0 μm to 5.0 μm;
a low-temperature semiconductor layer disposed between the high-temperature semiconductor layer and the Group III-V superlattice layer, wherein a thickness of the low-temperature semiconductor layer ranges from 5.0 nm to 20 nm;
a quasi-3D semiconductor layer disposed between the low-temperature semiconductor layer and the high-temperature semiconductor layer, wherein the quasi-3D semiconductor layer is a quasi-3D GaN layer, and a thickness of the quasi-3D semiconductor layer ranges from 0.4 μm to 1.0 μm; and
a gradient layer disposed between the Group III-V superlattice layer and the low-temperature semiconductor layer, wherein a proportion of a first Group III component in a portion of the gradient layer away from the substrate is less than a proportion of the first Group III component in a portion of the gradient layer proximate to the substrate.

5-10. (canceled)

11. The base structure according to claim 4, wherein the gradient layer comprises a plurality of gradient semiconductor layers stacked in layers;
the proportion of the first Group III component in the gradient layer decreases layer by layer along a direction away from the substrate;
the gradient layer is an AlGaN gradient layer, and the first Group III component is Al; and
the number of the plurality of gradient semiconductor layers ranges from 15 to 30.

12. (canceled)

13. The base structure according to claim 4, wherein the proportion of the first Group III component in the gradient layer gradually decreases along a direction away from the substrate, the proportion of the first Group III component in the gradient layer is less than the proportion of the first Group III component in any one of the semiconductor layers in the Group III-V superlattice layer, and a sum of a thickness of the gradient layer and a thickness of the Group III-V superlattice layer ranges from 0.2 μm to 0.5 μm.

14-15. (canceled)

16. The base structure according to claim 1, further comprising: a transition structure disposed between the Group III-V superlattice layer and the substrate, wherein the transition structure comprises a roughened semiconductor layer and a smooth semiconductor layer, the smooth semiconductor layer is disposed between the roughened semiconductor layer and the Group III-V superlattice layer, the smooth semiconductor layer is an AlN smooth layer, the roughened semiconductor layer is an AlN roughened layer, and at least one of the smooth semiconductor layer and the roughened semiconductor layer has a thickness ranging from 1.0 μm to 3.0 μm.

17-18. (canceled)

19. The base structure according to claim 16, wherein the base structure further comprises an auxiliary growth layer disposed between the roughened semiconductor layer and the substrate, the auxiliary growth layer is an Al layer, and a thickness of the auxiliary growth layer ranges from 0.3 nm to 1.0 nm.

20. (canceled)

21. The base structure according to claim 1, wherein the Group III-V superlattice layer comprises 15 to 60 lattice stack layers; or
at least one of the semiconductor layers has a thickness ranging from 1.7 nm to 16.7 nm.

22. (canceled)

23. The base structure according to claim 1, wherein the substrate is a Si substrate.

24. A semiconductor device, comprising:
a base structure according to claim 1; and
an epitaxial structure disposed on one side of the Group III-V superlattice layer away from the substrate.

25. The semiconductor device according to claim 24, wherein the epitaxial structure comprises the second Group III component.

26. A method for manufacturing a base structure, comprising:
providing a substrate;
forming a Group III-V superlattice layer on the substrate; wherein a step of forming the Group III-V superlattice layer on the substrate comprises forming a lattice stack layer, a step of forming the lattice stack layer comprises sequentially forming at least two semiconductor layers, and at least one semiconductor layer comprises a first Group III component and a second Group III component; in the step of forming the Group III-V superlattice layer on the substrate, the step of forming the lattice stack layer is performed multiple times to form a plurality of the lattice stack layers stacked on the substrate; and in a same lattice stack layer, a proportion of the first Group III component in a semiconductor layer away from the substrate is less than a proportion of the first Group III component in a semiconductor layer proximate to the substrate; and
configuring an epitaxial structure on one side of the Group III-V superlattice layer away from the substrate, wherein the epitaxial structure comprises the second Group III component.

27. The method according to claim 26, wherein the step of forming the lattice stack layer comprises: providing a first Group III component source to form a first semiconductor layer; and providing a first Group III component source to form a second semiconductor layer on the first semiconductor layer; and
in the step of forming the lattice stack layer, an amount of the first Group III component source provided to form the second semiconductor layer is less than an amount of the first Group III component source provided to form the first semiconductor layer.

28. The method according to claim 26, wherein the Group III-V superlattice layer comprises an AlGaN superlattice, the first Group III component is Al, and the second Group III component is Ga;
during a process of forming the Group III-V superlattice layer on the substrate, a temperature of an epitaxial growth apparatus is set to range from 1030° C. to 1100° C., and a pressure is set to range from 50 Torr to 100 Torr;
during a process of forming the first semiconductor layer, an amount of an Al source is provided and a proportion of an Al component in the Al component and a Ga component in the first semiconductor layer ranges from 10% to 30%; and
during a process of forming the second semiconductor layer on the first semiconductor layer, an amount of an Al source is provided and a proportion of an Al component in the Al component and a Ga component in the second semiconductor layer ranges from 5% to 15%.

29-30. (canceled)

31. The method according to claim 26, further comprising:
forming a low-temperature semiconductor layer on the Group III-V superlattice layer, wherein during a process of forming the low-temperature semiconductor layer on the Group III-V superlattice layer, a temperature of an epitaxial growth apparatus is set to range from 950° C. to 1050° C., a pressure is set to range from 350 Torr to 550 Torr, and a ratio of an amount of a provided Ga source to an amount of a provided N source is less than 1;
forming a quasi-3D semiconductor layer on the low-temperature semiconductor layer, wherein during a process of forming the quasi-3D semiconductor layer on the low-temperature semiconductor layer, a temperature of an epitaxial growth apparatus is set to range from 1000° C. to 1060° C., and a pressure is set to range from 450 Torr to 600 Torr; and
forming a high-temperature semiconductor layer on the quasi-3D semiconductor layer, wherein during a process of forming the high-temperature semiconductor layer on the quasi-3D semiconductor layer, a temperature of an epitaxial growth apparatus is set to range from 1060° C. to 1100° C., and a pressure is set to range from 100 Torr to 200 Torr.

32-35. (canceled)

36. The method according to claim 31, further comprising: after forming the Group III-V superlattice layer and before forming the low-temperature semiconductor layer, forming a gradient layer on the Group III-V superlattice layer, wherein during a process of forming the gradient layer, an amount of an Al source provided at a first moment is greater than an amount of an Al source provided at a second moment, the second moment is later than the first moment.

37. (canceled)

38. The method according to claim 36, wherein during a process of forming the gradient layer, the amount of the provided Al source is gradually reduced.

39. The method according to claim 26, further comprising: after providing the substrate and before forming the Group III-V superlattice layer on the substrate, forming a transition structure on the substrate;
wherein forming the transition structure on the substrate comprises: forming a roughened semiconductor layer on the substrate; and forming a smooth semiconductor layer on the roughened semiconductor layer;
wherein during a process of forming the roughened semiconductor layer on the substrate, a temperature of an epitaxial growth apparatus is set to range from 1030° C. to 1100° C., and a pressure is set to range from 50 Torr to 150 Torr; and
wherein during a process of forming the smooth semiconductor layer on the roughened semiconductor layer, a temperature of an epitaxial growth apparatus is set to range from 1030° C. to 1100° C., and a pressure is set to range from 50 Torr to 150 Torr.

40-42. (canceled)

43. The method according to claim 39, wherein forming the transition structure on the substrate further comprises: forming an auxiliary growth layer on the substrate before forming the roughened semiconductor layer; wherein during a process of forming the auxiliary growth layer on the substrate, a temperature of an epitaxial growth apparatus is set to range from 1000° C. to 1060° C., and a pressure is set to range from 50 Torr to 120 Torr.

44. (canceled)
